(19) United States
(12) Patent Application Publication
(10) Pub. No.: US 2013/0207662 A1
(43) Pub. Date: Aug. 15, 2013

(54) METHOD FOR TESTING LED LIGHT BAR

(71) Applicant: CHIH-CHEN LAI, Tu-Cheng (TW)

(72) Inventor: CHIH-CHEN LAI, Tu-Cheng (TW)

(73) Assignee: HON HAI PRECISION INDUSTRY CO., LTD., Tu-Cheng (TW)

(21) Appl. No.: 13/537,066

(22) Filed: Jun. 29, 2012

(30) Foreign Application Priority Data
Feb. 14, 2012 (TW) 101104618

(51) Int. Cl. G01R 31/44

(52) U.S. Cl. 324/414

(57) ABSTRACT

A method for testing LED light bar includes steps: providing a jig with a pair of aligning plates, and a testing device with an electrical clamp and a sensor; adjusting alignment of LEDs via the pair of aligning plates when soldering the LEDs; clamping one of the LEDs by the electrical clamp and supplying a current of microampere to the LED via the electrical clamp when soldering the LEDs; and detecting whether there is light emitted from the LED via the sensor when supplying the current of microampere to the LED.

### BACKGROUND

1. Technical Field

The present disclosure generally relates to method for testing electronic devices, and particularly to a method for testing light emitting diode (LED) light bar.

2. Description of Related Art

Recently, LED light bars are widely used for illumination and backlight display. Generally, LED light bars are constituted of a plurality of LEDs soldered on a circuit board and aligned in a straight line. Due to that the LEDs are firstly adhered to the circuit board by solder before the reflow soldering process, the LEDs are easily shifted from the predetermined positions when the solder is molten into liquid state during the reflow soldering process. Furthermore, the LEDs are easily affected by heat and vapor during the reflow soldering process of the LED bars, thereby failing to emit light. Thus, it is an important issue to guarantee the yield in manufacturing LED light bar.

Therefore, it is necessary to provide a method for testing LED light bar.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure.

FIG. 1 is a flow chart of a method for testing LED light bar in accordance with an exemplary embodiment of the present disclosure.

FIG. 2 is a schematic view showing the LED light bar to be tested.

FIG. 3 is a schematic view showing a jig in adjusting alignment of LEDs of the LED light bar in accordance with an exemplary embodiment of the present disclosure.

FIG. 4 is a schematic side view showing a testing device clamping one of the LEDs and testing the LED in accordance with an exemplary embodiment of the present disclosure.

### DETAILED DESCRIPTION

Reference will now be made to the drawings to describe an exemplary embodiment of the present method for testing LED light bar.

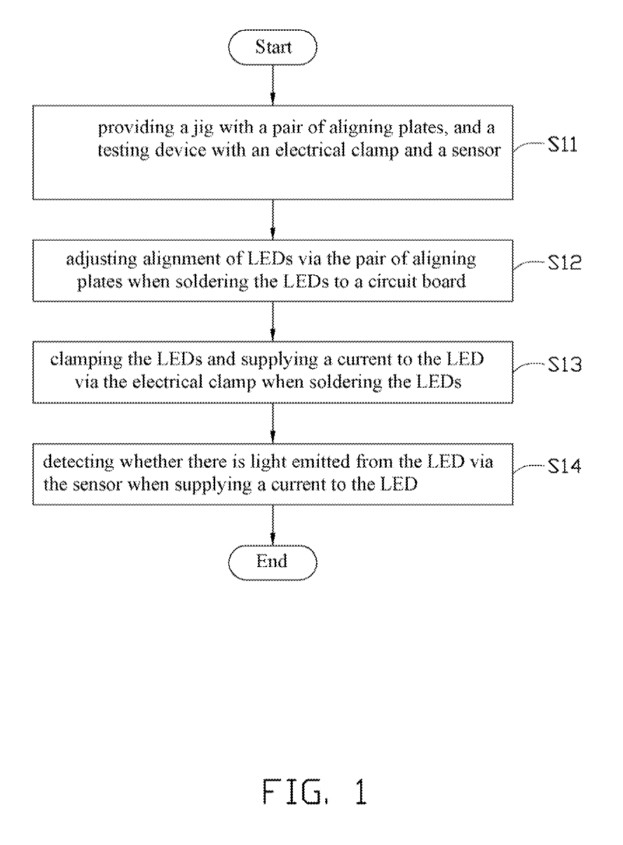

Referring to FIG. 1, a method for testing LED light bar, comprising following steps:

S11. providing a jig with a pair of aligning plates, and a testing device with an electrical clamp and a sensor;

S12. adjusting alignment of LEDs via the pair of aligning plates when soldering the LEDs to a circuit board;

S13. clamping the LEDs and supplying a current to the LED via the electrical clamp when soldering the LEDs; and

S14. detecting whether there is light emitted from the LED via the sensor when supplying a current to the LED.

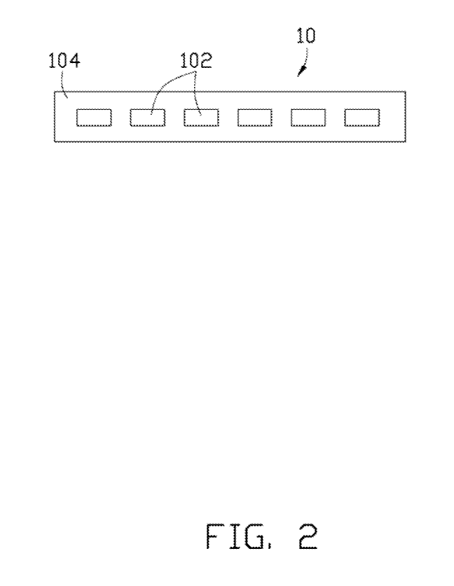

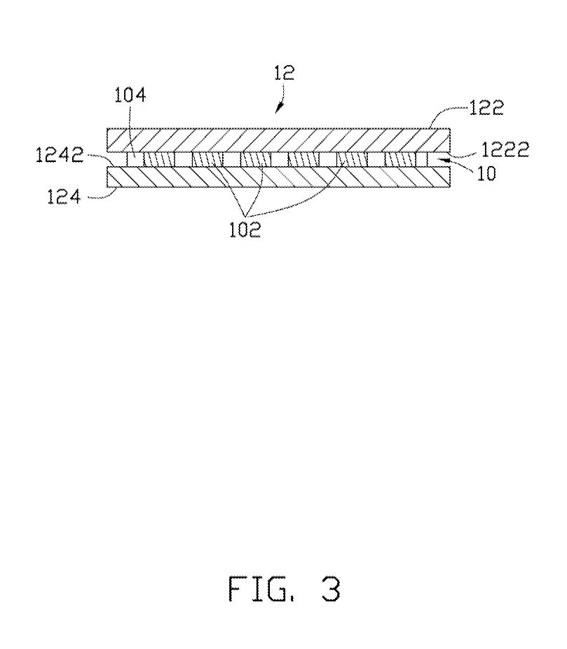

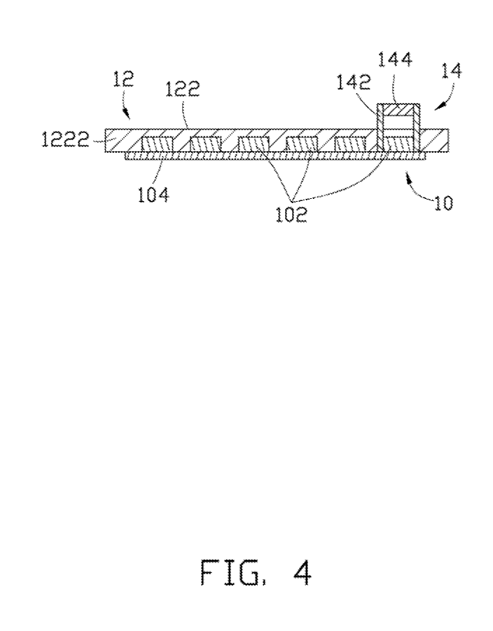

Referring to FIG. 2, an LED light bar 10 to be tested, in this embodiment, includes a bar-like circuit board 104 and a plurality of LEDs 102 uniformly soldered, for example by surface mounting technology (SMT), on the circuit board 104 and aligned in a straight line. Also referring to FIG. 3 and FIG. 4, the above mentioned steps are discussed as below.

In step S11, a jig 12 and a testing device 14 are provided. The jig 12 includes two aligning plates 122, 124. The aligning plate 122 includes an engaging surface 1222. The aligning plate 124 includes an engaging surface 1242. The testing device includes an electrical clamp 142 and a sensor 144.

In step S12, the aligning plates 122 and 124 are arranged in a manner to make the engaging surface 1222 opposite and substantially parallel to the engaging surface 1242. When the solder is molten into a liquid state during soldering the LEDs 102 to the circuit board 104, for example by reflow soldering process, the engaging surfaces 1222 and 1242 are moved inward towards each other to engage two lateral sides of the LEDs 102, thereby eliminating shift of LEDs 102 from their intended positions and ensuring the LEDs 102 aligned in a straight line after the molten solder solidifies.

In step S13, the LEDs 102 are clamped by the electrical clamp 142 one by one. When an LED 102 is clamped by the electrical clamp 142, the sensor 144 is arranged above the corresponding LED 102. Then a current is supplied to the LED 102 via the electrical clamp 142. In this embodiment, the current supplied to the LED 102 is a microampere current for driving the LED 102 to emit light at a low intensity. In this case, the microampere current is enough to drive the LED 102 to emit dim light. By such design, current leakage in the LED 102 which is difficult to be detected in a condition of supplying a large (i.e., rated) current to the LED 102 can be effectively avoided by the present disclosure.

In step S14, the sensor 144 performs a detecting function of light existence. When an existence of light emitted from the LED 102 is detected, the sensor 144 sends out a signal representing a successful testing result of the LED 102, which means that the LED 102 under test is alright and can function normally. When there is no existence of light emitted from the LED 102 detected, the sensor 144 sends out a signal representing a failed testing result of the LED 102, which means that the LED 102 is broken and cannot functional normally.

The above mentioned method can effectively ensure the LEDs 102 aligned in a straight line after a soldering process thereof, under the aligning function of the engaging surfaces 1222 and 1242. At the same time, the light emitting function of the LEDs 102 is also tested by the testing device 14.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A method for testing LED light bar, comprising:
providing a jig with a pair of aligning plates, and a testing device with an electrical clamp and a sensor;
adjusting alignment of LEDs via the pair of aligning plates when soldering the LEDs;
clamping one of the LEDs and supplying a current smaller than a rated current of the one of the LEDs to the one of the LEDs via the electrical clamp when soldering the LEDs; and
detecting whether there is light emitted from the one of the LEDs via the sensor when supplying the current to the one of the LEDs.

2. The method of claim 1, wherein the LED light bar comprises a bar-like circuit board and the LEDs are uniformly soldered on the circuit board in a straight line.

3. The method of claim 1, wherein the sensor is arranged above the one of the LEDs to be tested when soldering the LEDs.

4. The method of claim 1, wherein the pair of aligning plates each comprises an engaging surface, and the aligning plates are arranged in a manner to make the two engaging surfaces opposite and substantially parallel to each other when adjusting alignment of the LEDs.

5. The method of claim 4, wherein the engaging surfaces are moved inward towards each other to engaging two lateral sides of the LEDs when solder is molten into a liquid state during soldering the LEDs.

6. The method of claim 1, wherein the LEDs are clamped by the electrical clamp one by one.

7. The method of claim 1, wherein the current supplied to the one of the LEDs is a microampere current for driving the LEDs to emit light with a low intensity.

8. The method of claim 1, wherein the sensor sends out a signal representing that the one of the LEDs is alright when the sensor detects an existence of light emitted from the one of the LEDs.

9. The method of claim 1, wherein the sensor sends out a signal representing that the one of the LEDs is failed when the sensor detects no existence of light emitted from the one of the LEDs.
